(19) United States
(12) Patent Application Publication
(10) Pub. No.: US 2024/0098890 A1
(43) Pub. Date: Mar. 21, 2024

(54) ELECTRONIC DEVICE AND ELECTRONIC APPARATUS

(71) Applicant: PanelSemi Corporation, New Taipei City (TW)

(72) Inventors: Chao-Jung CHEN, New Taipei City (TW); Chin-Tang LI, New Taipei City (TW)

(21) Appl. No.: 18/368,741

(22) Filed: Sep. 15, 2023

Related U.S. Application Data
(60) Provisional application No. 63/407,400, filed on Sep. 16, 2022.

(51) Int. Cl. H05K 1/02; H05K 1/14; H05K 1/18

(52) U.S. Cl. CPC H05K 1/0298; H05K 1/144; H05K 1/147; H05K 1/18; H05K 2201/10106; H05K 2201/10121; H05K 2201/10189

(57) ABSTRACT

An electronic device and an electronic apparatus with a mating structure. The electronic device comprises a first substrate with a first face and a second face opposite to each other, a plural of tiles on the first face and with a second substrate and a patterned layer, a trace layer between the tiles and the first substrates and electrically connected to the patterned layer, and a connection component disposed at a second surface of the first substrate and electrically connected to the trace layer.

### CROSS REFERENCE TO RELATED APPLICATIONS

This Non-provisional application claims priority under 35 U.S.C. § 119(a) on Patent Application No(s). 63/407,400 filed in United States of America on Sep. 16, 2022, the entire contents of which are hereby incorporated by reference.

### BACKGROUND

### Technology Field

The disclosure relates to an electronic device and an electronic apparatus, especially relates to an electronic device and an electronic apparatus with a mating structure.

### Description of Related Art

With the development in display technology, consumers' demand for full-screen displays is increasing. A full-screen display can provide consumers with a larger screen space and a better visual experience to meet their needs in watching videos, playing games, working, and more. In addition to offering an immersive experience, a full-screen display can also provide higher efficiency, expanding its applications other than display technology.

Currently, most full-screen devices use conductive wires at edges of a substrate thereof for electrical connection, the conductive wiring layer still requires an aggregation-and-convergence segment for gathering the conductive wires to connect to an external circuit board, thus reducing the maximum size of the full screen.

### SUMMARY

One or ones of the exemplary embodiments of this disclosure are to provide an electronic device.

One or ones of the exemplary embodiments of this disclosure are to provide an electronic apparatus including an electronic device and a mating structure applicable to the electronic device.

An electronic device comprises one or more first substrates, one or more tiles, a trace layer, and one or more connection components. Each of the first substrates defines a first surface and a second surface opposite to each other. Each of the tiles is disposed on the first surface of one or ones of the first substrates in a first direction along the first surface thereof. Each of the tile includes a second substrate and a patterned layer, and the patterned layer is formed on the second substrate and away from the first surface of one or ones of the first substrates. The trace layer is arranged between one or ones of the tiles and one of the first substrates and electrically connected to the patterned layer of the one or ones of the tiles. The one or ones of the connection components is/are disposed at the second surface of the corresponding of the first substrates and electrically connect the trace layer.

In one embodiment, the connection components includes a connector.

In one embodiment, the connection components includes an exterior extension board.

In one embodiment, the electronic device further comprises one or more conjunctions electrically connecting the exterior extension board to the trace layer, wherein the conjunction is provided with a first through hole through the first substrate, a second through hole through exterior extension board, and a conductive member disposed in the first through hole and the second through hole.

In one embodiment, the electronic device further includes a third substrate disposed on the second surface(s) of one or ones of the first substrates in a second direction along the second surface thereof; the third substrate comprises one or more openings, and one of the connection components is arranged in a respective one of the openings.

In one embodiment, one of the openings locates at or around a geometric center of the third substrate.

In one embodiment, the third substrate includes a plural sub-third substrates tiled with another, and one of the openings is formed between adjacent two of the sub-third substrates.

In one embodiment, the third substrate of the electronic device is or further comprises first attachment means for sticking to an object.

In one embodiment, the first attachment means is functioned of magnetics, or gecko-like or suction micro-structures.

In one embodiment, the first attachment means is disposed to the first substrate, and an external surface of the first attachment means is coplanar to an external surface of the third substrate.

In one embodiment, the first attachment means can be disposed to the third substrate, and an external surface of the first attachment means is coplanar to an external surface of the third substrate, in which the third substrate is provided with an indentation for the first attachment means accommodate.

In one embodiment, the first attachment means is disposed on the third substrate away from the first substrate.

In one embodiment, the electronic device further includes one or more cover members covering at least part of one or ones of the connection components.

In one embodiment, the electronic device further includes one or more cover members covering at least part of one or ones of the connection components through one or ones of the openings.

In one embodiment, one or ones of the tiles further include a plural of self-emission members electrically connecting the patterned layer.

In one embodiment, the one or ones of the tiles further include a plural of photodiodes.

In one embodiment, the one or ones of the tiles further includes a plural of touch sensors.

In one embodiment, the self-emission members are light-emitting diodes (LEDs), mini-LEDs, micro-LED s or organic LEDs (OLEDs).

The electronic device further includes an image capture device underneath the first substrate, and a light traveling passage in response to the image capture device is formed by the first and second substrates.

The electronic device further includes an image capture device disposed in a corresponding one of the openings, and a light traveling passage in response to the image capture device is formed by the first and second substrates.

In one embodiment, the trace layer is arranged on the corresponding one of the second substrates.

In one embodiment, the trace layer is arranged on the corresponding one of the first substrates.

In one embodiment, the trace layer is arranged on a bottom surface of the corresponding one of the tiles.

In one embodiment, one or ones of the first substrates further defines a conductive layer formed on the second face thereof, which electrically either connects or disconnects the trace layer.

In one embodiment, one or ones of the first substrates are resilient.

In one embodiment, the one or ones of the tiles (second substrates) are resilient.

In one embodiment, the one or ones of the third substrates are resilient.

In one embodiment, one or ones of the first substrates, one or ones of the tiles and one or ones of third substrate respectively define a Young's modulus value, and the Young's modulus value of either one or both of the first substrate(s) and the tiles(s) is/are less than the Young's modulus value of the third substrate.

In one embodiment, the trace layer electrically connects the patterned layer(s) of one or ones of the tiles by one or more top jumper structure, each of the top jumper structures is provided with a top through hole and a top conductive member, and the top conductive member is disposed in the top through hole and electrically connects the patterned layer with the trace layer.

In one embodiment, the trace layer electrically connects the patterned layer of one or ones of corresponding tiles by one or ones of the top jumper structure, each of the top jumper structures defines a top through hole and a top conductive member, the top conductive member is disposed in the top through hole and electrically connects the patterned layer with the trace layer, and one end of the top through hole is enclosed by the patterned layer.

In one embodiment, at least a partial region of either one or both of the patterned layer and the trace layer are defined as thin film.

In one embodiment, the partial region defined as thin film of either one or both of the patterned layer and the trace layer has a thickness no greater than ¼ mil.

In one embodiment, the first substrate, the trace layer and the tile are arranged in one-to-one-to-one manner.

In one embodiment, the first substrate, the trace layer and the tile are arranged in one-to-one-to-one manner, and the trace layer may comprise plural trace units.

In one embodiment, the trace layer and the first substrate are arranged in one-to-one manner and is defined as one trace layer-first substrate unit, and plural tiles are disposed on the trace layer-first substrate unit.

In one embodiment, the trace layer and the tile are arranged in one-to-one manner and is defined as one trace layer-tile unit, and plural trace layer-tile unit are disposed on one first substrate.

In one embodiment, the trace layer and the tile are arranged in one-to-one manner and is defined as one trace layer-tile unit, and plural trace layer-unit are disposed on an integrated substrates tiled by plural first substrates.

In one embodiment, the exterior extension board is a resilient board.

In one embodiment, the connection component includes an adaptor board, and the adaptor board electrically connects to the trace layer by electrically connecting the exterior extension board.

In one embodiment, the adaptor board can be disposed in the opening of the third board.

In one embodiment, the adaptor board is attached onto the first substrate or the third substrate.

In one embodiment, the adaptor board is a rigid board.

In one embodiment, the adaptor board can be accommodated in the cover member.

In one embodiment, one or ones of the first substrates, one or ones of the tiles and the third substrate are connected with one another through an adhesive layer.

In one embodiment, the electronic device is a display device, a touch-display device or an X-ray sensor device.

In one embodiment, one or ones of the first substrates together define a first common substrate contour, one or ones of the tiles together define a common tile contour, one or ones of the third substrate together define a third common substrate contour, either one or both of the first common substrate contour and the third common substrate contour are no greater than the common tile contour.

The present invention also disclose an electronic apparatus comprising the electronic device abovementioned and a mating structure. The mating structure comprises a mating board, and one or ones of the mating areas defined on the mating board and corresponding to one or ones of the of the electronic devices aforementioned. Each of the mating areas electrically connected with a corresponding one of the connection components in a removable manner.

In one embodiment, the mating board at least includes second attachment means correspond to the first attachment means aforementioned for sticking with each other.

In one embodiment, the first attachment means or/and the second attachment means comprises magnetic, magnetizable materials, Gecko-like dry adhesive surfaces, electrostatic-like mechanics, adhesive materials, or suction micro-structures.

In one embodiment, the mating areas defines a cave formed on the mating board and accommodating the corresponding one of the connector of the electronic device.

In one embodiment, the mating board define at least one-dimensional curve.

In one embodiment, the mating board is/includes an aluminum board.

### BRIEF DESCRIPTION OF THE DRAWINGS

The present invention will become more fully understood from the subsequent detailed description and accompanying drawings, which are given by way of illustration only, and thus are not limitative of the present invention, and wherein:

FIG. 1A and FIG. 1B respectively show a side view and a back view of one embodiment of the present invention;

FIG. 2A and FIG. 2B respectively show a side view and a back view of another embodiment of the present invention;

FIG. 3A and FIG. 3B respectively show a side view and a back view of one embodiment provided with the third substrate of the present invention;

FIG. 4A and FIG. 4B are side views showing two embodiments of the present invention provided with the third substrate and the first attachment means;

FIG. 5A and FIG. 5B show are schematic diagrams showing assembly of the present invention;

FIG. 6A to FIG. 6D are back views showing embodiments of the present invention provided with cover member;

FIG. 7A to FIG. 7H are side views showing embodiments of the present invention provided with additional boards;

FIG. 8A to FIG. 8D are side views showing various embodiments of the connection component connecting to the first substrates of the present invention;

FIG. 9A and FIG. 9B are schematic diagrams showing a mating structure applicable to the present invention; and

FIG. 10A to FIG. 10C are side views showing embodiments of interaction between the mating structure and the present invention.

### DETAILED DESCRIPTION OF THE DISCLOSURE

The disclosure will become more fully understood from the detailed description and accompanying drawings, which are given for illustration only, and thus are not limitative of the present disclosure.

The present disclosure will be apparent from the following detailed description, which proceeds with reference to the accompanying drawings, wherein the same references relate to the same elements.

In addition, the quantity of the components in the following description is just for exemplary which is not used to limit the scope of the present invention.

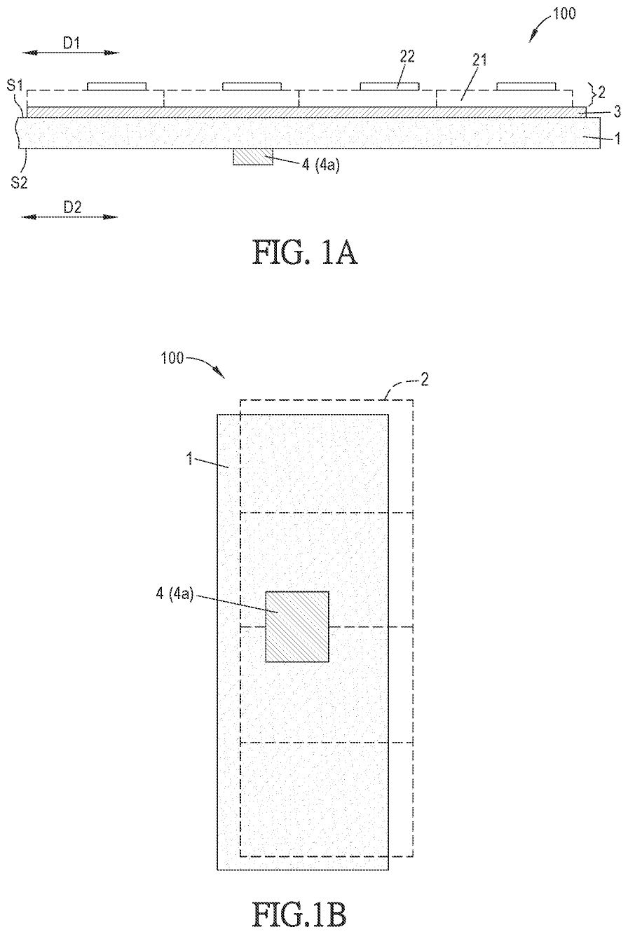

FIG. 1A is a side view, and FIG. 1B is a back view of the electronic device 100 according to the present invention. The electronic device 100 mainly comprises one or more first substrates 1, one or more tiles 2, one or more trace layers 3 and one or more connection components 4. In FIG. 1, just one single substrate is illustrated for easy comprehension, and plural tiles 2 are provided in this case. The first substrate 1 defines a first surface S1 and a second surface S2 opposite to each other. Multiple tiles 2 are disposed on the first surface S1 of the first substrate 1 in a first direction D1 along the first surface S1; in other words, the tiles 2 are tiled on the first substrate 1. Each of the tiles 2 includes a second substrate 21 and a patterned layer 22, and the patterned layer 22 is formed on the second substrate 21 and away from the first surface S1 of the first substrate 1. The trace layer 3 is arranged between the tiles 2 and the first substrate 1, and the trace layer 3 is electrically connected to the patterned layers 22 of the tiles 2. The connection component 4 is disposed at the second surface S2 of the first substrate 1 and electrically connects the trace layer 3.

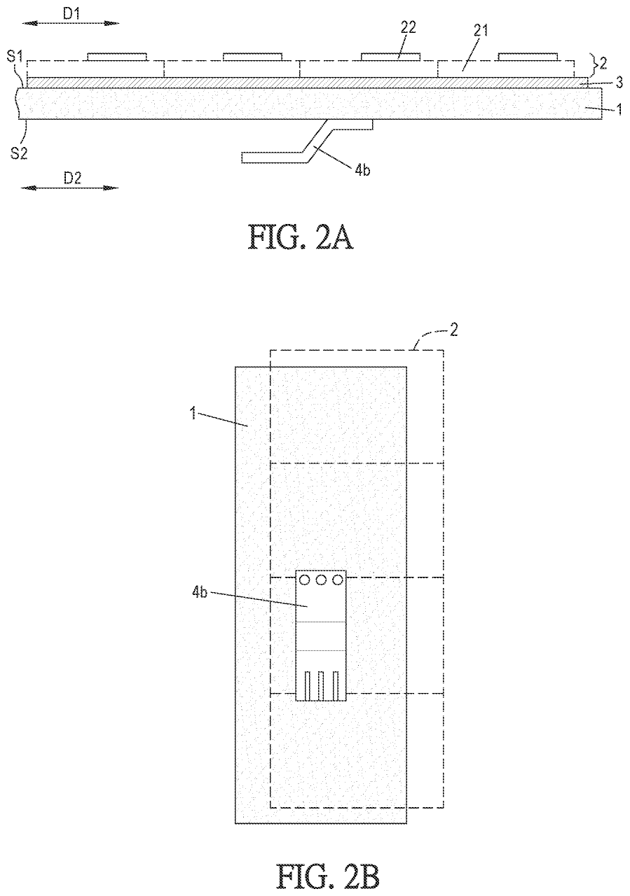

The connection component 4 may include a connector-typed one as illustrated in FIG. 2A, or an exterior extension board 4b as shown in FIG. 2B, or both of them applied in one case, but not limited thereto. For easy comprehension, the connection component is a generic wording comprising the connector 4a and the exterior extension board 4b.

The electronic device 100 referred in FIG. 1A to FIG. 2B is the broadest embodiment of the present invention, on which other embodiments are based.

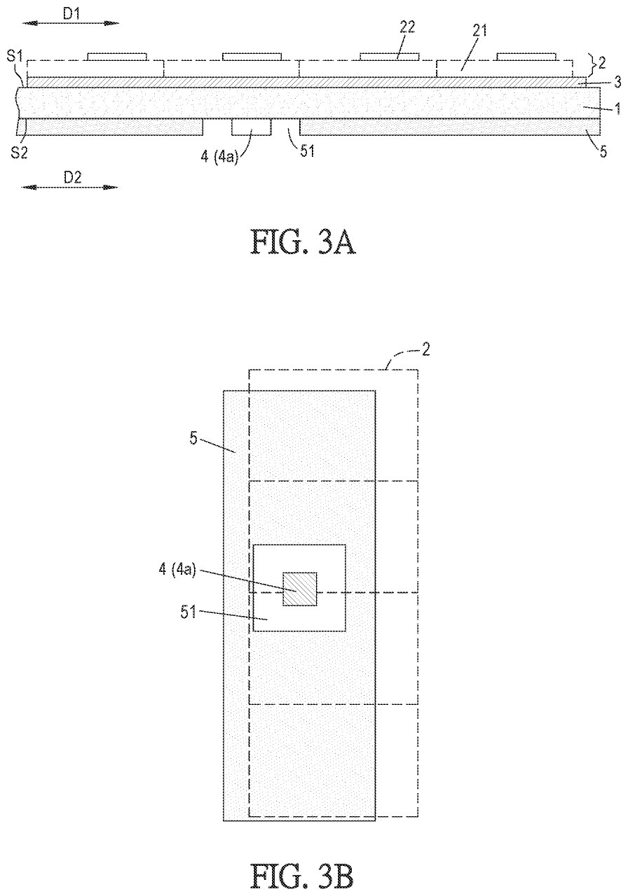

Referring to FIG. 3, one or more third substrate 5 is provided to the electronic device 100. For easy comprehension in this case, just one single third substrate 5 is illustrated. The third substrate 5 is disposed on the second face S2 of the first substrate 1 in a second direction D2 along the second face S2. The third substrate 5 defines one or more openings 51; in some cases, one of the openings 51 is window-like, in some cases, one of the openings 51 is a gap interrupting the third substrate 5 into sub-third substrates. A corresponding one of the connection components 4 is disposed in each of the openings 51. Only one opening 51 and one connection components 4 are illustrated in FIG. 3A just for easy comprehension. The third substrate 5 can be a single board or tiled by multiple sub-third substrates. In addition, the third substrate 5 is resilient or rigid per se, in which the third substrate 5 can be formed of molding materials. The opening 51 is formed through the third substrate 5, and the connector 4a illustrated in FIG. 3A joins the first substrate 1 through the opening 51 and electrically connects the trace layer 3.

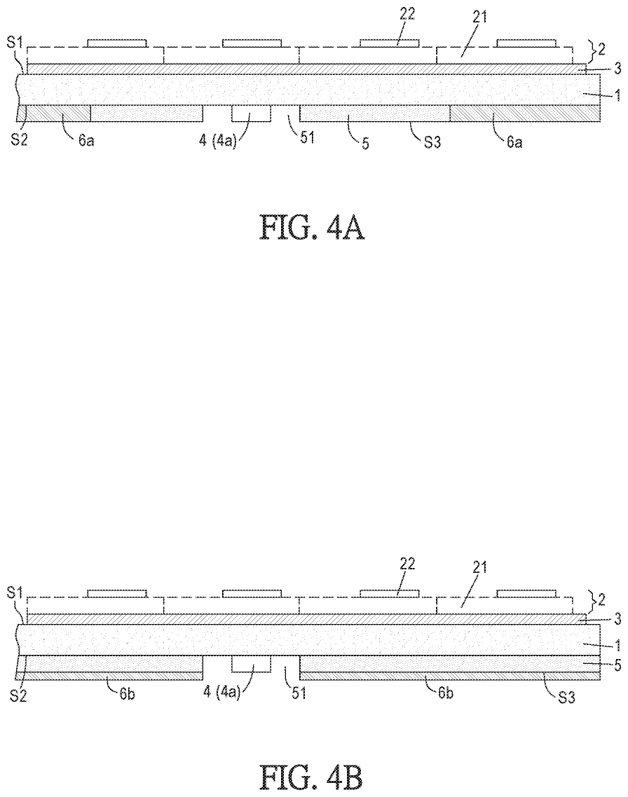

In FIGS. 4A and 4B, first attachment means is provided to the electronic devise 100 of the present invention. The first attachment means is disposed at the second surface S2 of the first substrate 1. In FIG. 4A, the first attachment means 6a is disposed on the second surface S2 of the first substrate 1 and is coplanar to an external surface S3 of the third substrate 5. In FIG. 4B, the first attachment mean 6b is disposed on the external surface S3 of the third substrate 5 away from the second surface S2 of the first substrate 1. The first attachment means can attach, mount or stick the electronic device 100 to an object. In one case, the first attachment means includes magnetic or magnetizable materials, for example, a magnetic tape; in another case, the first attachment means at least includes Gecko-like dry adhesive surfaces; in another case, the first attachment means at least includes electrostatic-like mechanics, adhesive materials, or suction micro-structures. The first attachment means will provide the electronic device easy attachment to the object, which may be a frame, a board or a wall, and there would be various approaches to meet the requirement.

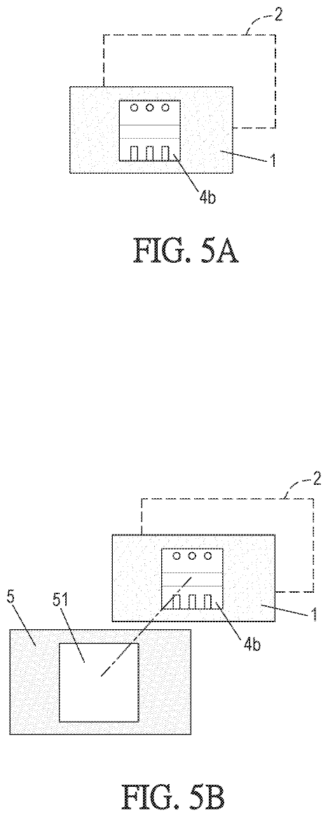

Referring to FIG. 5A, the first substrate 1 and the tile 2 are arranged in one-to-one manner, in this case one or ones of the trace layers 3 are disposed between the first substrate 1 and the tile 2. Referring to FIG. 5B, the third substrate 5, the first substrate 1, and the tile 2 are arranged in one-to-one-to-one manner. The quantity of the first substrate 1, the tile 2 and the third substrate 5 for arrangement to each other are not limited in this invention.

In addition, quantities of how the first substrate 1, and the tile 2 and the trace layer 3 are arranged are also not limited.

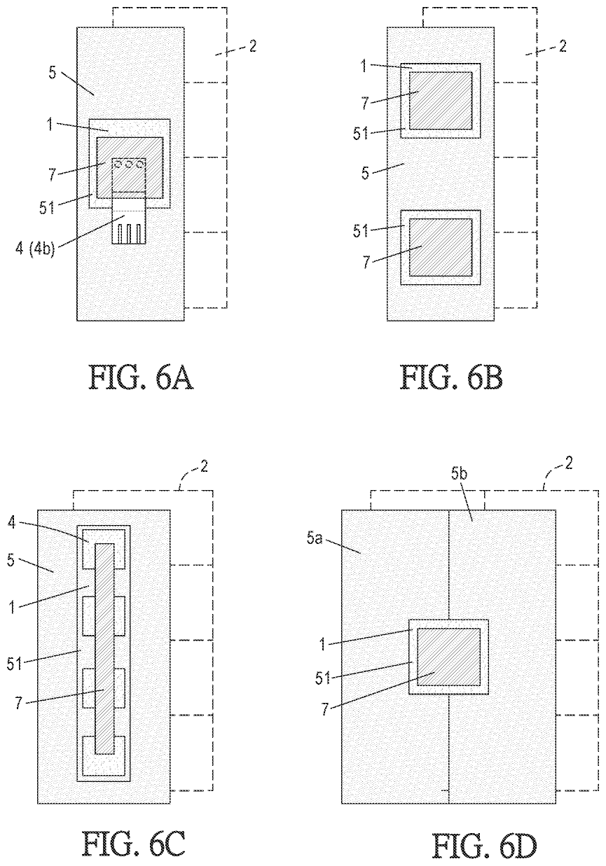

In one embodiment, a cover member 7 is further provided in FIGS. 6A to 6D. The cover member 7 in these cases correspond to the opening 51 of the third substrate 5, and the cover member 7 covers at least part of one or ones of the connection components. The quantity of the cover member 7 and its corresponding openings are also not limited. In another case of the basic embodiment, the cover member 7 is directly disposed on the first substrate 1, which is not shown in drawings. For further description, in FIG. 6A, the third substrate 5 has one single opening 51, and one single connection component 4 (an exterior extension board 4b in this figure) is disposed in the opening 51, and one single cover member 7 is provided to cover at least partial of the exterior extension board 4b. In this case, the cover member 7 accommodated itself in one single opening 51, and the cover member 7 is capable of enclosing or not any layer of the third substrate 5. In FIG. 6B, a single third substrate 5 has two openings 51, and each of the opening 51 is cover by one cover member 7. However, the quantity of the third substrate 5 is not limited, for example, the amount of the third substrate 5 can more than one, and each of the third substrate 5 comprises a single opening 51 covered by a single cover member 7. Referring to FIG. 6C, four tiles 2 are disposed on one first substrate 1 and one third substrate 5, in which the third substrate 5 has four openings 51 and each of the opening 51 is arranged corresponding to each tile 2. In this case, a single cover member 7 covers the four openings 51 at the same time. In one embodiment as shown in FIG. 6D, a complete opening 51 is formed by tow adjacent third substrates 5a, 5b, and a connection component is disposed in the opening 51, wherein the opening is covered by the cover member 7.

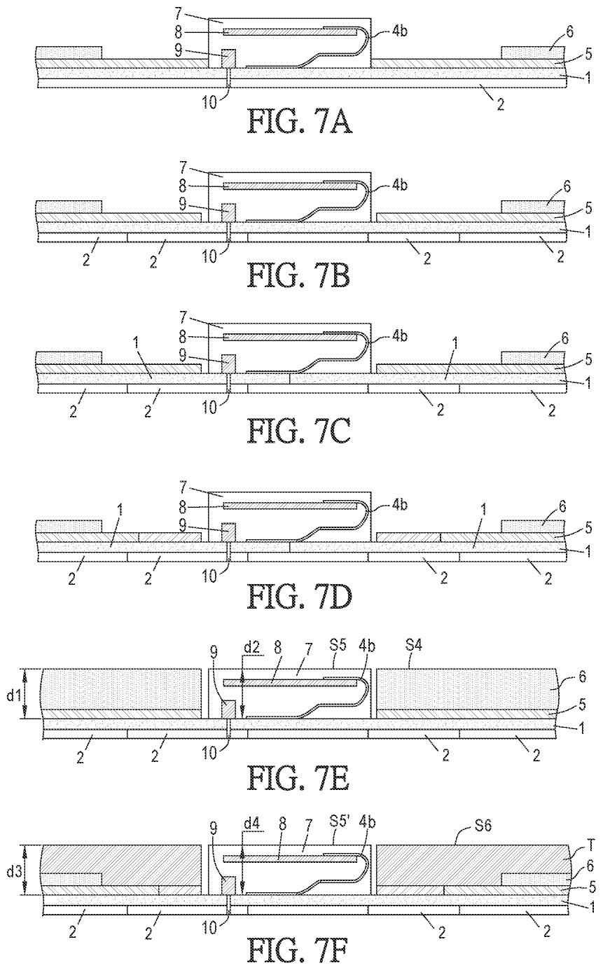

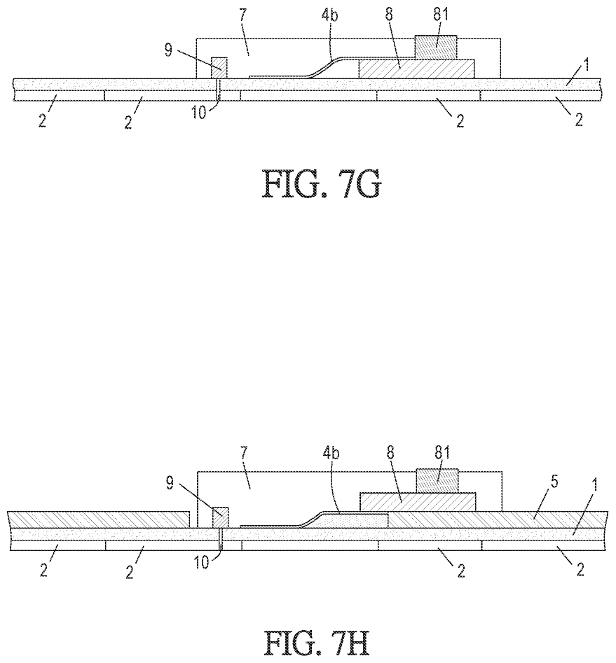

Referring to FIG. 7A, an adaptor board 8 is connected to the exterior extension board 4b. To be noted, the exterior extension board 4b is one single component of multiple function, or several boards or components assembled. Further, an image capture device 9, for example, a camera, is disposed underneath the first substrate 1, for example, in the opening 51 of the third substrate 5. In such case, a light traveling passage 10 is produced by passing through both of the first substrate 1 and a corresponding one of the tiles 2, or by passing through the first substrate 1 and a seam between the tiles 2, in which the light traveling passage 10 corresponds to the image capture device 9 for light traveling. In addition, the image capture device 9 can be integrated with the cover member 7, or not. In this embodiment, the first attachment means 6 is disposed on the third substrate 5 away from the first substrate 1.

FIG. 7B, FIG. 7C and FIG. 7D are three other derived examples from FIG. 7A. In FIG. 7B, plural tiles 2 are disposed on the first substrate 1. In FIG. 7C, the plural tiles 2 are disposed on plural tiled first substrates 1, and the amount of the tiles and the first substrates 1 are different. In FIG. 7D, the amount of the third substrate 5 is also more than one.

In FIG. 7E, a total thickness d1 of the third substrate 5 and the first attachment means 6 is equal to a height d2 of the cover member 7, so an external surface S4 of the first attachment means 6 is coplanar with an external surface S5 of the cover member 7. In another case shown in FIG. 7F, a thickened layer T is disposed on the third substrate 5 and the first attachment mean 6, and a total thickness d3 of the third substrate 5, the first attachment means 6 and the thickened layer T is equal to a height of the cover member d4, so an external surface S6 of the thickened layer T is coplanar with an external surface S5′ of the cover member 7. The thickened layer T can be a film, a paste, or any approaches the like to meet the coplanar purpose.

Referring to FIG. 7G and FIG. 7H, the adaptor board 8 can be attached on the first substrate 1 or the third substrate 5. The adaptor board 8 is further provided with a connector 81.

In one embodiment, the shape of the cover member 7 and the opening 51 are different. For example, the contour of the opening 51 can be a rectangular shape, and the contour of the cover member 7 can be a circle shape. In another embodiment, either one or all of the first substrates 1 and the second substrate 21 of one or tiles 2 and each of the third substrates 5 define a polygonal outline.

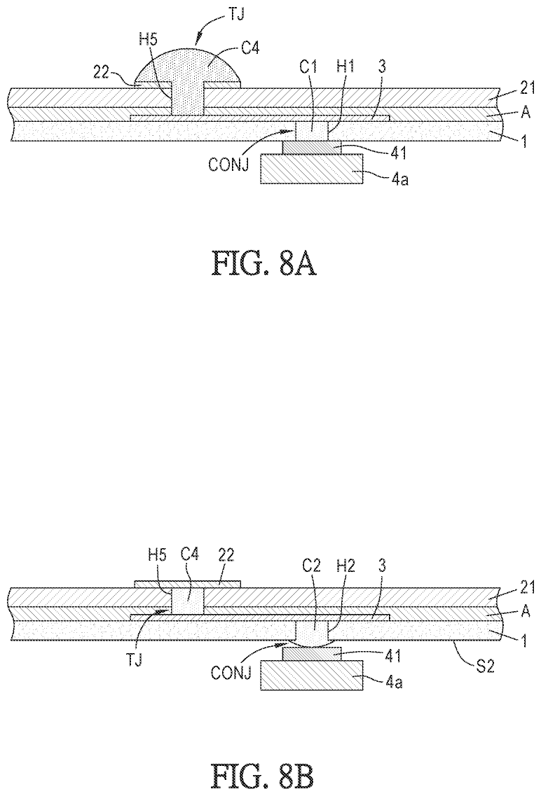

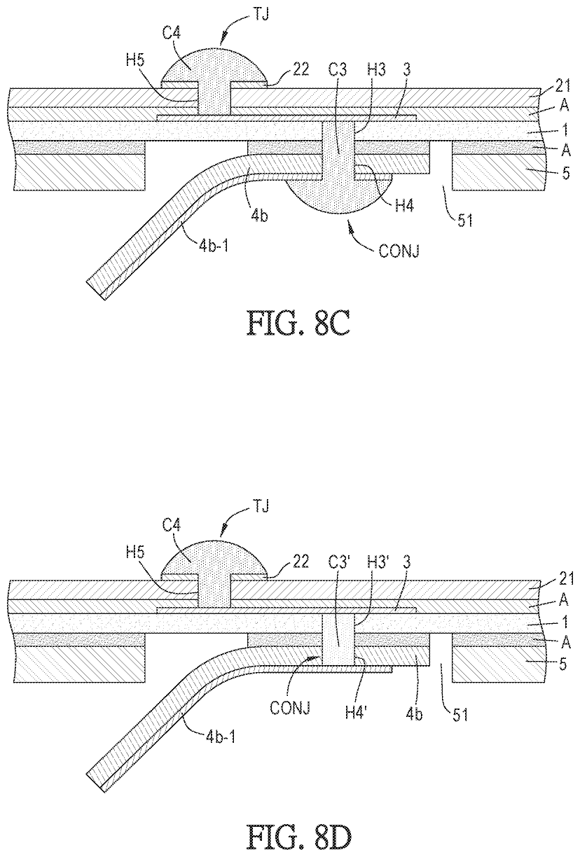

Please refer to FIG. 8A to FIG. 8C, one or more conjunctions CONJ are used for connecting the connector 4a or exterior extension board 4b to the trace layer 3, and types of the conjunctions CONJ are disclosed as exemplary.

In FIG. 8A, the conjunction CONJ is defined by a through hole H1 passing through the first substrate 1 corresponding to the connector 4a and the trace layer 3, and a connective member C1 disposed in the through hole H1. The connector 4a further comprises a conductive pad 41. In this embodiment, one end of the through hole H1 is sealed by the conductive pad 41, and a second end is sealed by the trace layer 3. The connector 4a electrically connects to the conductive member C1 in the through hole H1, and then electrically connects to the trace layer 3.

In FIG. 8B, the conjunction CONJ is defined by a through hole H2 passing through the first substrate 1 corresponding to the trace layer 3 and the connector 4a, a conductive member C2 disposed in the through hole H2. In this embodiment, one end of the through hole H2 is sealed by the trace layer 3, and the other end communicates with the second surface S2 of the first substrate 1. The connector 4a further comprises a conductive pad 41, and the connector 4a electrically connects to the conductive member C2 in the through hole H2, and then electrically connects to the trace layer 3.

In FIG. 8C, the conjunction CONJ is defined by a first through hole H3, a second through hole H4 and a conductive member C3. The first through hole H3 passes through the first substrate 1, the second through hole H4 is arranged in the exterior extension board 4b, and the first through H3 is communicated with the second through hole H4, and the conductive member C3 is disposed in the first through hole H3 and the second through hole H4. In addition, the exterior extension board 4b comprises a conductive layer 4b-1. Therefore, the trace layer 3 is electrically connected to the conductive member C3, and the conductive element 4b-1 of the exterior extension board 4b. In this embodiment, one end of the conductive structure C3 is exposed by the second through hole H4. However, in FIG. 8D, an end of the conductive structure C4 near the second through hole H4 is sealed by the conductive layer 4b-1 of the exterior extension board 4b.

In FIG. 8A to FIG. 8C, the patterned layer 22 of the tile 2 are connected to the trace layer 3 by one or more top jumper TJ structures. Each of the top jumper TJ structures is defined by a top through hole H5 and a top conductive member C4. The top through hole H5 passes through the second substrate 21 of the tile 2, and the top conductive member C4 is disposed in the top through hole H5 and electrically connects the patterned layer 22. The top conductive member C4 is also electrically connects to the trace layer 3. Therefore, the patterned layer 22 electrically connects to the trace layer by the top conductive member C4 in the top through hole H5. In this embodiment, one end of the top conductive member C4 is seal by the trace layer, and the other end thereof is exposed by the top through hole H5 as shown in FIG. 8A, FIG. 8C and FIG. 8D. However, the other end of the top conductive member C4 can be covered and sealed by the patterner layer 22 as shown in FIG. 8B.

The quantity of the conjunctions CONJ and the top jumper TJ structures are not limited. The conductive member C1, C2, C3, C3′, C4 are made of conductive materials, such as metals, non-metal conductive materials or a composite comprising one of the metals or non-metal conductive materials. Furthermore, in FIG. 8A to FIG. 8D, one or more adhesive layers A is provided between the first substrates 1 and the second substrate of the tile 2, and between the first substrate 1 and third substrate 5 for bonding.

In one case, one or ones of the first substrates are resilient, the second substrate of one or ones of the tiles are resilient, and one or ones of the third substrate are resilient. If one or ones of the first substrates defines at least a one-dimensional curve, and after the tiles and the third substrates are attached to the first substrate, the electronic device is capable of curvature. In one case, one or ones of the first substrates, one or ones of the tiles and the third substrates respectively defines a Young's modulus value, and either one of the Young's modulus value of one or ones of the first substrates is less than the Young's modulus value of the third substrates.

In one case, either one or both of the patterned layer of the tile and the trace layer include molybdenum materials. In one case, at least a segment of either one or both of the patterned layer of the tile and the trace layer are defined as thin film, and the thin film define a thickness which is no greater than ¼ mil.

In one case, one or ones of the tiles further include a plural of self-emission members electrically connecting the patterned layer, and the self-emission members are light-emitting diodes (LEDs), mini-LEDs, micro-LED s or organic LEDs (OLEDs).

In one case, one or ones of the first substrates defines a conductive layer formed on the second face thereof, which is capable of electrically connecting or disconnecting the trace layer. In one case, the conductive layer includes copper materials. In one case, the conductive layer defines a thickness greater than a thickness of the trace layer.

In one case, one or ones of the first substrates together define a first common substrate contour, one or ones of the tiles together define a common tile contour, one or ones of the third substrates together define a third common substrate contour, either one or both of the first common substrate contour and the third common substrate contour are no greater than the common tile contour.

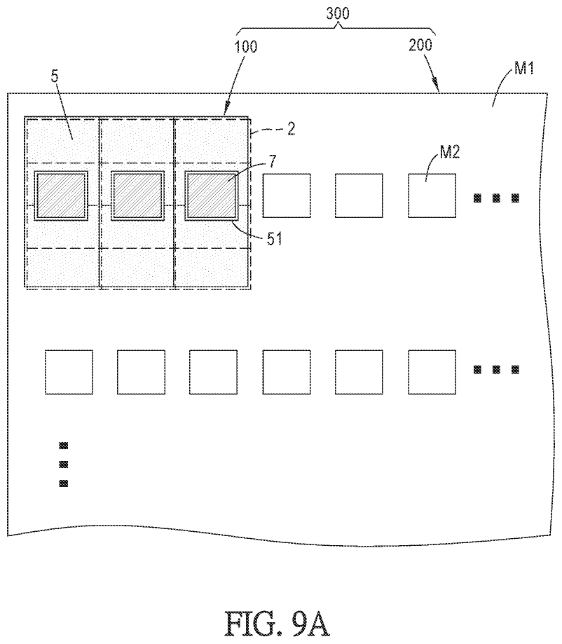

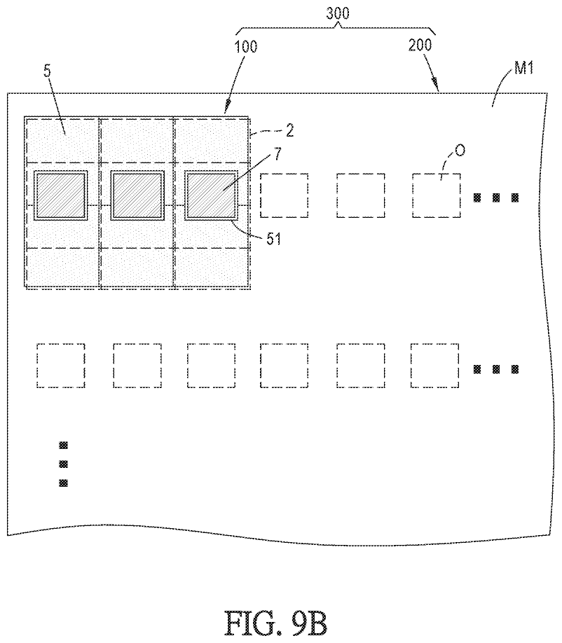

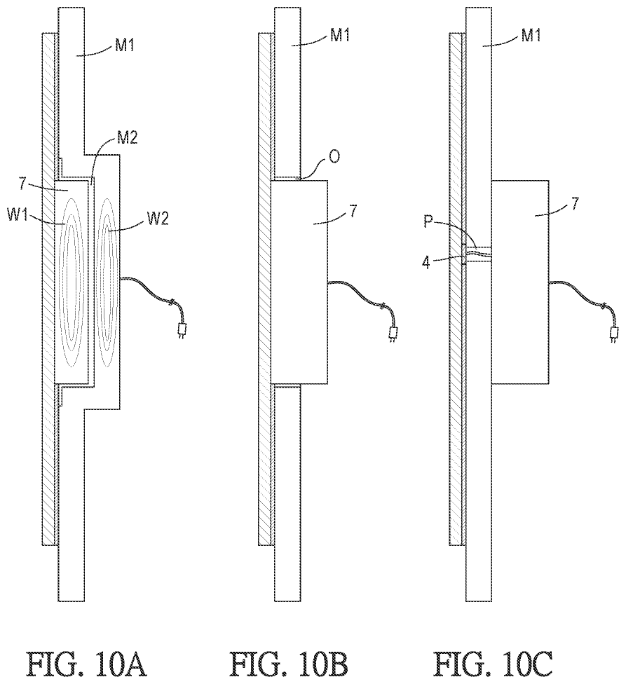

Please referring to FIG. 9A and FIG. 9B, a mating structure 200, applicable to the electronic device of this invention is disclosed; here we've got an electrical apparatus 300 including the mating structure 200 and the electronic device. The mating structure 200 includes a mating board M1, and one or ones of the mating areas defined on the mating board M1 and corresponding to the to one or ones of the of the electronic devices; each mating areas defines a plurality conductive members disposed on the mating board M1 and electrically connected with one or ones of connection components in a removable manner. To be noted, the mating areas can be designed in a continual manner, or the mating areas can be designed in a continuous manner. It depends on the placement density of the electronic devices and how the electronic devices keep the electrical connection to the mating board M1. The mating area can be formed as a cave M2 for accommodating the cover member 7 as shown in FIG. 9A and FIG. 10A. The mating area can also be a through opening O accommodating or passing by the cover member 7 as shown in FIG. 9B and FIG. 10B.

To be noted, the mating board M1 would be provided with second attachment means of magnetic or magnetizable materials, Gecko-like structures, electrostatic-like materials, adhesive materials or suction micro-structures, in response to the first attachment means. In one case, the mating board M1 is or includes an aluminum board. In one case, the mating board define at least one-dimensional curve, the electronic devices are capable of fitting the curvature of the mating board M1 for attachment.

In one case, a trace W1 is further provided in the cover member 7, and another trace W2 is provided in the cave M2 of mating board, and the traces W1 and W2 are electromagnetic induction units for wireless charging or are wireless communication circuits for wireless communication between the electronic devices and the mating board 1, such as illustrated in FIG. 10A.

In one case, the mating area would be a through opening O, and the power supply and signal transmit are integrated in one piece and are covered by the cover member 7 such as illustrated in FIG. 10B, but not limited.

In one case, as illustrated in FIG. 10C, the connection component 4 and the cover member 7 is detachable to the first substrate 1 and mounted on the mating board M1; a passageway P is defines by the mating area, and the power supply and signal transmit integrated in one piece in the cover member 7 may electrically connected to the first substrate 1 by wiring, but not limited.

To summarize the present invention, an electronic device comprises at least kinds of components: a series of first substrates, each with two opposing surfaces. Multiple tiles are positioned parallel to one side surface(s) of some or all of the first substrates. Each tile at least includes a second substrate and a patterned layer, with the patterned layer situated on the second substrate and distanced from the first substrates. A layer of trace is strategically placed between the tiles and their corresponding first substrate, creating an electrical connection to the patterned layer. On the other side surface of the appropriate first substrates, there are some connection components that serve the electrically connection between the trace layer and an exterior electrical device. Approaches of the electrical connections between the first substrates and the tiles, or between the first substrates and the connection components are not limited. The connection component(s) is bonded to the backside of the first substrate, instead of extending from the frontside or the edge the first substrate, and it allows to keep the maximum size of the full screen. For further application, multiple of electronic devices can be tiled together to form a seamless huge device together. It should be notice that the electronic device here is not limited to a display, and the screen here is not only indicates a display screen.

What is claimed is:

1. An electronic device, comprising:
one or more first substrates; wherein each of the first substrates defines a first surface and a second surface opposite to each other;
one or more tiles disposed on the first surface(s) of one or ones of the first substrates in a first direction along the first surface thereof; wherein each of the tile includes a second substrate and a patterned layer, and the patterned layer is formed on the second substrate and away from one or ones of the first substrates;
a trace layer arranged between one or ones of the tiles and a corresponding one of the first substrates and electrically connected to the patterned layer; and
one or more connection components disposed at the second surface of the corresponding of the first substrates and electrically connect the trace layer.

2. The electrical device as claimed in claim 1, wherein a corresponding one of the connection components includes a connector.

3. The electrical device as claimed in claim 1, wherein a corresponding one of the connection components includes an exterior extension board.

4. The electrical device as claimed in claim 3, further including one or more conjunctions electrically connecting the exterior extension board to the trace layer, wherein the conjunction is provided with a first through hole through the first substrate, a second through hole through exterior extension board, and a conductive member disposed in the first through hole and the second through hole.

5. The electronic device as claimed in claim 1, further including a third substrate stacked on the second surface(s) of one or ones of the first substrates along the second surface thereof, wherein the third substrate comprises one or more openings, and one of the connection components is arranged in a respective one of the openings.

6. The electronic device as claimed in claim 5, wherein the third substrate is or further comprises first attachment means for sticking to an object.

7. The electronic device as claimed in claim 6, wherein the first attachment means is functioned of magnetic, magnetizable materials, Gecko-like dry adhesive surfaces, electrostatic-like mechanics, adhesive materials, or suction micro-structures.

8. The electronic device as claimed in claim 1, further includes one or more cover members covering at least part of one or ones of the connection components.

9. The electronic device as claimed in claim 5, further includes one or more cover members covering at least part of one or ones of the connection components through one or ones of the openings.

10. The electronic device as claimed in claim 1, wherein one or ones of the tiles further include a plural of self-emission members electrically connecting the patterned layer.

11. The electronic device as claimed in claim 1, further including an image capture device disposed underneath the first substrate, and a light traveling passage in response to the image capture device is formed by the first and second substrates.

12. The electronic device as claimed in claim 1, wherein the trace layer is arranged on the corresponding one of the first substrates.

13. The electronic device as claimed in claim 1, wherein one or ones of the first substrates, one or ones of the tiles and one or ones of third substrate respectively define a Young's modulus value, and the Young's modulus value of either one or both of the first substrate(s) and the tiles(s) is/are less than the Young's modulus value of the third substrate(s).

14. The electronic device as claimed in claim 1, wherein one or ones of the first substrates defines a conductive layer formed on the second face thereof, which electrically either connects or disconnects the trace layer.

15. The electronic device as claimed in claim 1, wherein the trace layer electrically connects the patterned layer(s) of one or ones of the tiles by one or more top jumper structure, each of the top jumper structures is provided with a top through hole and a top conductive member, and the top conductive member is disposed in the top through hole and electrically connects the patterned layer with the trace layer.

16. The electronic device as claimed in claim 1, wherein at least a partial region of either one or both of the patterned layer and the trace layer are defined as thin film.

17. The electronic device as claimed in claim 16, wherein the partial region defined as thin film of either one or both of the patterned layer and the trace layer has a thickness no greater than ¼ mil.

18. An electronic apparatus, comprising:
the electronic device according to claim 1, and
a mating structure, wherein the mating structure comprises:
a mating board, and
one or ones of the mating areas defined on the mating board and corresponding to one or ones of the connection components of the electronic devices according to claim 1, wherein one of the mating areas electrically connected with a corresponding one of the connection components in a removable manner.

19. The electronic apparatus as claimed in claim 18, wherein the mating board at least includes second attachment means corresponding to first attachment means of the electronic device for sticking with each other.

20. The electronic apparatus as claimed in claim 18, wherein each of the mating areas defines a cave formed on the mating board and accommodating the corresponding one of the connector of the electronic device.
